(19) United States
(12) Patent Application Publication
(10) Pub. No.: US 2012/0193802 A1
(43) Pub. Date: Aug. 2, 2012

(54) GLOB TOP SEMICONDUCTOR PACKAGE

(76) Inventors: Chin-Tien Chiu, Taichung City (TW); Chih-Chin Liao, Changhua (TW); Peng Fu, Kunshan (CN)

(21) Appl. No.: 13/019,126

(22) Filed: Feb. 1, 2011

(51) Int. Cl. H01L 23/48

(52) U.S. Cl. 257/773; 257/E23.01

(57) ABSTRACT

A semiconductor package is disclosed including a substrate, a solder mask layer, one or more semiconductor die mounted to the solder mask layer and electrically coupled to the substrate, and a glob top cover over the semiconductor die. The solder mask further includes a dam protruding above surrounding areas of the solder mask layer and a cavity recessed into the solder mask layer for limiting flow of the glob top cover when the glob top material is applied.

### BACKGROUND OF THE INVENTION

1. Field of the Invention

Embodiments of the present invention relate to semiconductor packages and in particular glob top semiconductor packages.

2. Description of the Related Art

The strong growth in demand for portable consumer electronics is driving the need for high-capacity storage devices. Non-volatile semiconductor memory devices, such as flash memory storage cards, are becoming widely used to meet the ever-growing demands on digital information storage and exchange. Their portability, versatility and rugged design, along with their high reliability and large capacity, have made such memory devices ideal for use in a wide variety of electronic devices, including for example digital cameras, digital music players, video game consoles, PDAs and cellular telephones.

A typical semiconductor package includes a substrate such as a printed circuit board, and one or more semiconductor die mounted and electrically coupled to the substrate, such as for example by wire bonds between the one or more semiconductor die and the substrate. In order to seal and protect the semiconductor die and wire bonds, it is typical to encapsulate the die and wire bonds in a mold compound in a transfer molding process. During the transfer molding process, the substrate and die are placed between upper and lower mold plates, and epoxy resin is injected around the die and possibly the substrate to encapsulate the package. While an effective protection, this type of encapsulation process involves time and cost, and the epoxy resin is injected under a large force and at an elevated temperature, both of which can adversely affect the semiconductor die.

Another process for encapsulating semiconductor die on a substrate is flow forming, also commonly referred to as glob top packaging. In glob top packaging, a discrete amount of epoxy is applied to the package, over the semiconductor die, for example at room temperature and pressure. The epoxy flows over the semiconductor die and is then cured to provide a solid cover over the semiconductor die. It is known to dig trenches into a substrate to limit the flow of the liquid epoxy when it is first applied to the semiconductor device. There is time and cost associated with forming this trench in the substrate.

### BRIEF DESCRIPTION OF THE DRAWINGS

FIG. 1 is a flowchart showing the assembly of a semiconductor device according to the present technology.

FIG. 2 is a flowchart showing further details of the steps for building the dam and cavity in the solder mask layer.

FIG. 3 is an edge view of a substrate according to an embodiment of the present technology.

FIG. 4 is a top view of a substrate according to an embodiment of the present technology.

FIG. 5 is an edge view of a substrate including a solder mask layer on the top and bottom surfaces according to an embodiment of the present technology.

FIG. 6 is a top view of a substrate including a cavity in the solder mask layer according to an embodiment of the present technology.

FIG. 7 is an edge view of a substrate including a solder mask layer on the top and bottom surfaces according to an embodiment of the present technology.

FIG. 8 is a top view of a substrate including a cavity and a dam in the solder mask layer according to an embodiment of the present technology.

FIG. 9 is a perspective view of the substrate including a cavity and a dam in the solder mask layer according to an embodiment of the present technology.

FIG. 10 is an edge view of a semiconductor device including a semiconductor die wire bonded to a substrate according to an embodiment of the present technology.

FIG. 11 is a top view of a semiconductor device including a semiconductor die wire bonded to a substrate according to an embodiment of the present technology.

FIG. 12 is an edge view of a semiconductor device including a glob top cover according to an embodiment of the present technology.

FIG. 13 is a top view of a semiconductor device including a glob top cover according to an embodiment of the present technology.

FIG. 14 is a perspective view of a semiconductor device including a glob top cover according to an embodiment of the present technology.

FIG. 15 is an edge view of a semiconductor device including a glob top cover extending into the cavity according to an alternative embodiment of the present technology.

FIG. 16 is an edge view of a semiconductor device including a glob top cover extending up a side wall of the dam according to an alternative embodiment of the present technology.

### DETAILED DESCRIPTION

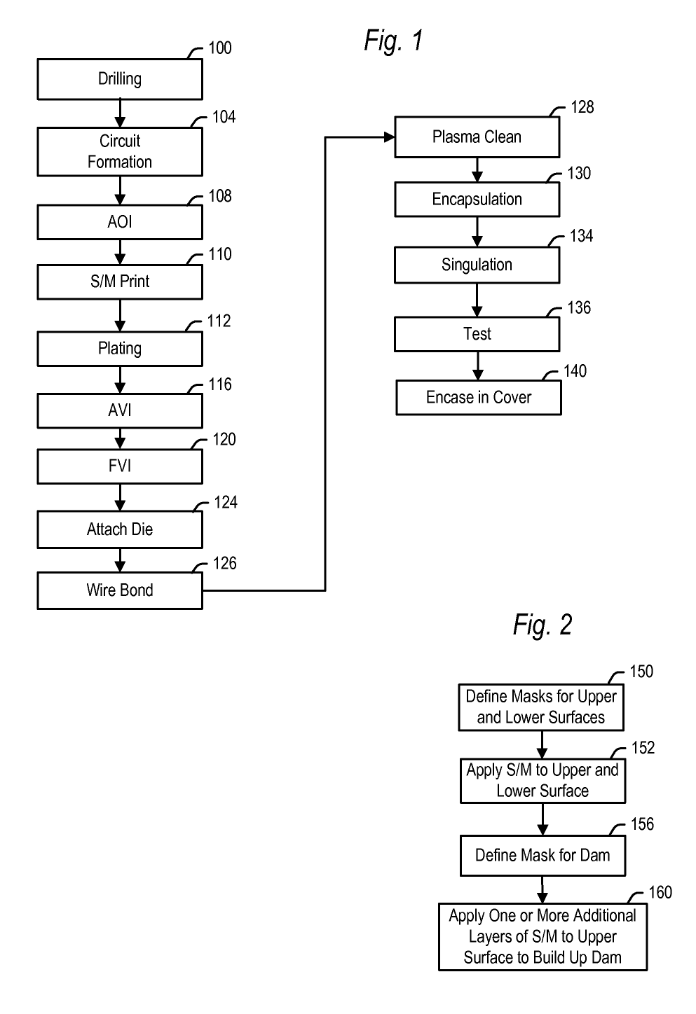

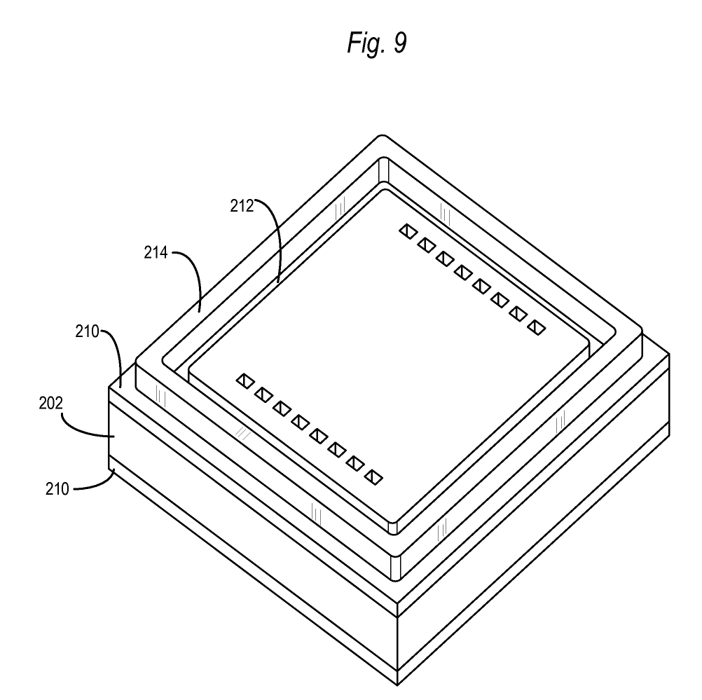

Embodiments will now be described with reference to FIGS. 1 through 16, which relate to a glob top semiconductor device. It is understood that the present invention may be embodied in many different forms and should not be construed as being limited to the embodiments set forth herein. Rather, these embodiments are provided so that this disclosure will be thorough and complete and will fully convey the invention to those skilled in the art. Indeed, the invention is intended to cover alternatives, modifications and equivalents of these embodiments, which are included within the scope and spirit of the invention as defined by the appended claims. Furthermore, in the following detailed description of the present invention, numerous specific details are set forth in order to provide a thorough understanding of the present invention. However, it will be clear to those of ordinary skill in the art that the present invention may be practiced without such specific details.

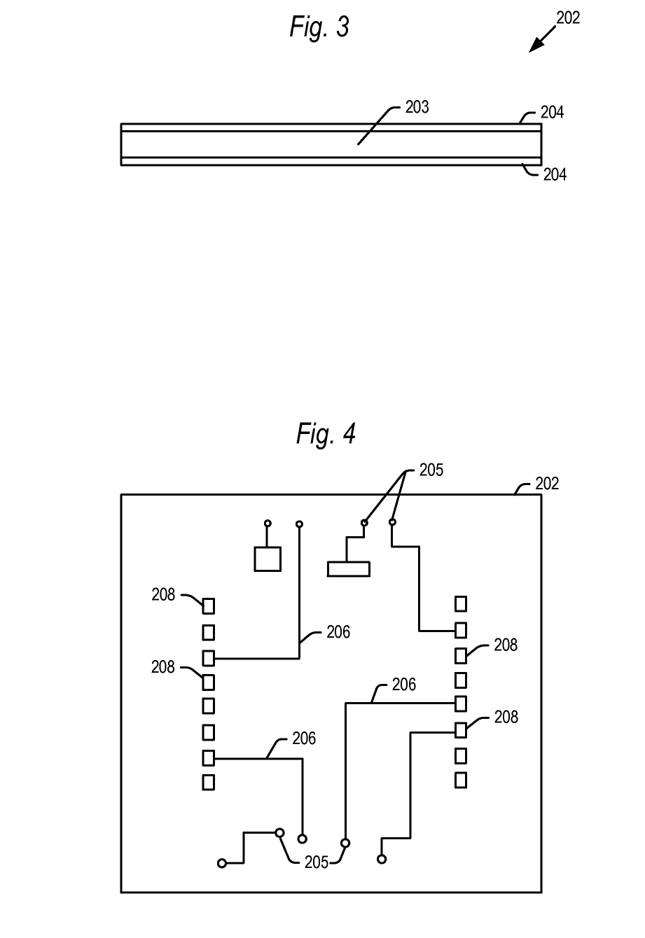

An embodiment of the present technology will now be explained with reference to the flowcharts of FIGS. 1 and 2, and the top, edge and perspective views of FIGS. 3 through 16. Although FIGS. 3 through 16 each show an individual semiconductor device 200, or a portion thereof, it is understood that the device 200 may be batch processed along with a plurality of other devices 200 on a substrate panel to achieve economies of scale. The number of rows and columns of devices 200 on the substrate panel may vary.

The substrate panel begins with a plurality of substrates 202 (again, one such substrate is shown in FIGS. 3 through 16). The substrate 202 may be a variety of different chip carrier mediums, including a printed circuit board (PCB), a leadframe or a tape automated bonded (TAB) tape. Where substrate 202 is a PCB, the substrate may be formed of a core 203 having top and bottom conductive layers 204. The core may be formed of various dielectric materials such as for example, polyimide laminates, epoxy resins including FR4 and FR5, bismaleimide triazine (BT), and the like. Although not critical to the present invention, the core may have a thickness of between 40 microns (μm) to 200 μm, although the thickness of the core may vary outside of that range in alternative embodiments. The core may be ceramic or organic in alternative embodiments.

The conductive layers surrounding the core may be formed of copper or copper alloys, plated copper or plated copper alloys, copper plated steel, or other metals and materials known for use on substrate panels. The conductive layers may have a thickness of about 10 μm to 25 μm, although the thickness of the layers may vary outside of that range in alternative embodiments. In further embodiments, instead of a single conductive layer on opposite sides of the core, there may be multiple conductive layers on one or both sides of the core.

In a step 100, the substrate 202 is drilled to define through-hole vias 205 in the substrate 202. The vias 205 (some of which are numbered in the figures) are by way of example, and the substrate may include many more vias 205 than is shown in the figures, and they may be in different locations than are shown in the figures. Conductance patterns are next formed in one or more of the conductive layers provided on the core in step 102. The conductance pattern is shown in the top layer in FIG. 4. It is understood that one or more of the remaining conductive layers may also have conductance patterns defined therein as well.

The conductance pattern(s) may include electrical traces 206 and contact pads 208 (some of which are numbered in the figures). The traces 206 and contact pads 208 shown are by way of example, and the substrate 202 may include more traces and/or contact pads than are shown in the figures, and they may be in different locations than are shown in the figures. Other structures may be provided in the conductance pattern such as for example test pins for testing the operation of the semiconductor device 200. The conductance pattern in the various conductive layers of the substrate 202 may be formed by a variety of known processes, including for example various photolithographic processes.

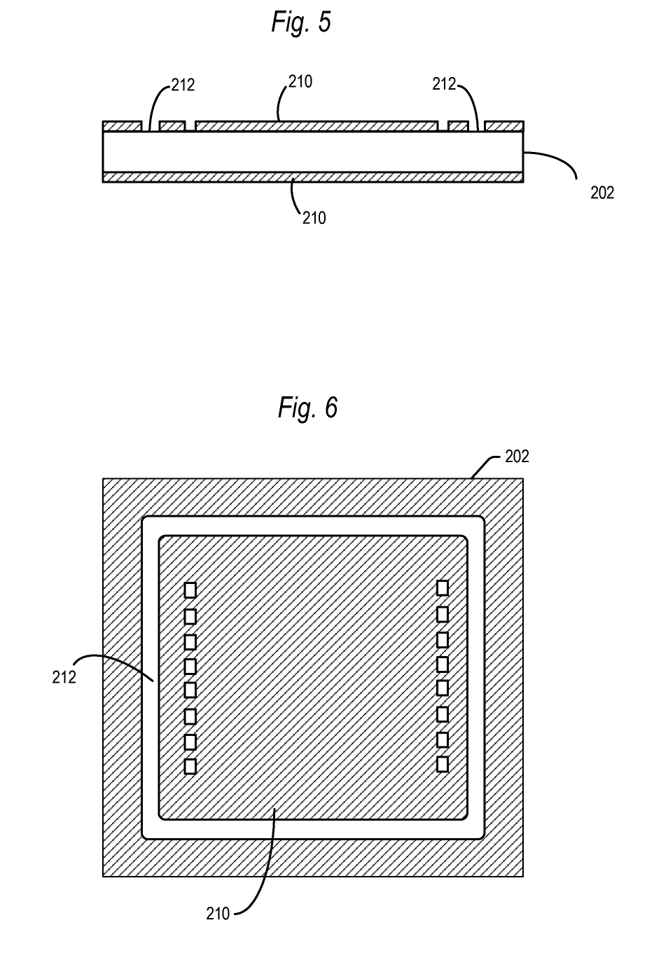

Referring again to FIG. 1, the substrate 202 may next be inspected in an automatic optical inspection (AOI) in step 104. Once inspected, a solder mask may be applied to the substrate 202 in step 106. The solder mask is a layer of polymer that provides a protective coating for the copper traces of the conductance pattern and prevents solder from bleeding beyond the exposed contact pads and test pins, thereby preventing short circuits. Moreover, in accordance with the present system, a dam and cavity may be defined in the solder mask to control the formation of the glob top cover as explained below. Further details of forming the solder mask layer in step 106 are described now with respect to the flowchart of FIG. 2 and the edge, top and perspective views of FIGS. 5-9.

The application of the solder mask layer may be performed by methods including by silk screening and by photolithography. In silk screening for example, a stencil mask is created for the top surface and a stencil mask is created for the bottom surface in step 150. In both stencil masks, areas of the mask are blocked off with a non-permeable material to form a stencil, which is a negative of the solder mask to be applied; that is, the open spaces on the stencil mask are where the polymer will appear in the solder mask layer on the substrate. The stencil mask for the lower surface would have blocked areas corresponding to any contact pads, test pins and/or contact fingers to be left uncovered by the solder mask on the lower surface. The stencil mask for the upper surface would have blocked areas corresponding to any contact pads to be left uncovered by the solder mask on the upper surface. Additionally, in accordance with the present technology, the mask for the upper surface would have an area blocked corresponding to a cavity that is to be defined in the solder mask layer on the upper surface.

In step 152, the solder mask is applied to the upper and lower surfaces using the masks for the upper and lower surfaces defined in step 150. Solder mask gets deposited on the upper and lower surfaces through the masks for the respective surfaces. Areas of the substrate 202 covered by a blocked area of the mask do not receive solder mask.

The edge and top views of FIGS. 5 and 6 show the applied solder mask layers 210. As seen in the top view of FIG. 6, the contact pads 208 of FIG. 4 are left exposed through the solder mask. Moreover, a cavity 212 is formed devoid of solder mask. The thickness of the solder mask on the upper and lower surfaces of the substrate may for example be 10 μm to 30 μm, though it may be thinner or thicker than that in further embodiments. In embodiments, the solder mask may for example be type PSR4000 AUS-308, manufactured by Taiyo Ink Mfg. Co., Ltd., having a place of business in Tokyo, Japan. The solder mask may be from other providers in further embodiments.

The cavity 212, devoid of solder mask 210, may be a generally rectangular band, rectangular band with rounded corners, or a generally circular band. The cavity may have a constant width of 450 to 550 μm, though it may be wider or narrower than that in further embodiments, and may have a varying width around its length in further embodiments. The cavity 212 may be provided near to an outer periphery of the substrate 202, and may be large enough so that a semiconductor die may be mounted to the solder mask 210, as explained below, radially inward of the cavity 212. The substrate may be visible at the bottom of the cavity. The substrate visible at the bottom of the cavity may either be a portion of the conductive layer 204 on the core 203, or the core 203 itself.

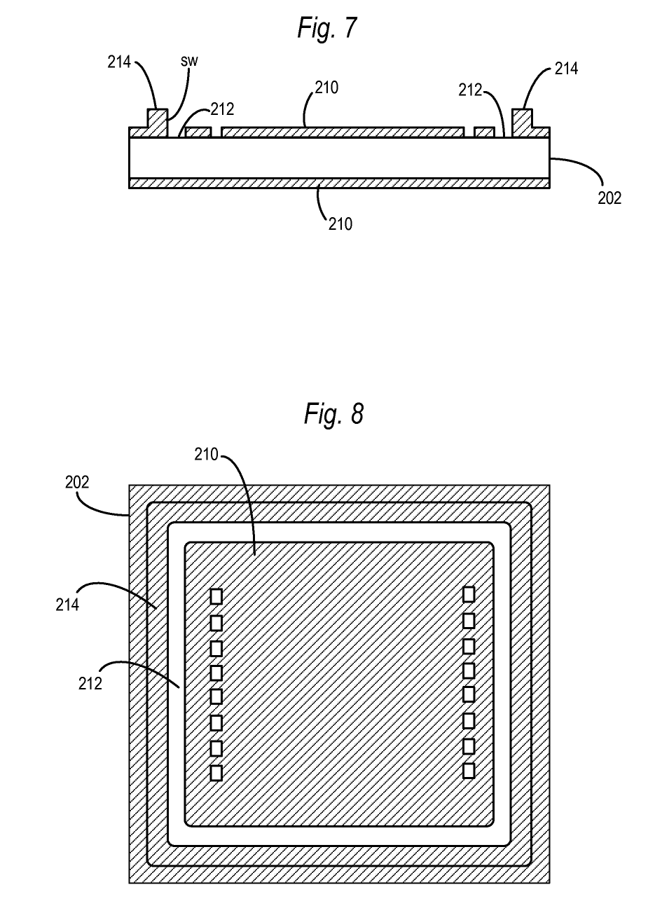

In step 156, a further stencil mask is defined blocking all areas except for a band located radially adjacent to, and outward of, the cavity 212. The band may also have the same shape as the cavity 212 so that the radially innermost portion of the band aligns with the radially outermost portion of the cavity 212. This stencil mask is then used to apply one or more additional layers of solder mask onto the top surface of the substrate in step 160. As the stencil mask blocks all areas except for the band, the new layer(s) of solder mask are applied onto the original layer of solder mask only in the area of the band so as to define a dam 214 shown for example in the edge, top and perspective views of FIGS. 7, 8 and 9.

The dam 214 may have a height of between 25 μm to 35 μm above the surface of the original solder mask layer, though the height may vary to be higher or lower than that in further embodiments. The dam 214 may have a constant width of 150 to 250 μm, though it may be wider or narrower than that in further embodiments, and may have a varying width around its length in further embodiments.

As seen in FIGS. 7-9, the radially innermost portion of the dam 214 aligns with the radially outermost portion of the cavity 212 to define a common side wall, sw in FIG. 7, having a height equal to the height of the original solder mask layer 210 plus the height of the dam 214. As shown, the dam 214 extends near to, but not to, the outer perimeter of the substrate 202. In further embodiments, the cavity 212 and dam 214 may be sized and positioned so that a radially outermost wall of dam 214 aligns around the outer perimeter of the substrate 202.

The solder mask may be applied by other methods to define the cavity 212 and dam 214 in further embodiments. One such additional example is by photolithography. There are different known photolithographic methods of applying the solder mask, but in one example, a uniform layer of liquid photoimageable solder mask (LPISM) is applied to the top and bottom surfaces. A mask having areas blocked in a negative of the desired final solder mask pattern is positioned over the top surface, and the LPISM not covered by the blocked areas is then exposed to a developer and cured. The uncured areas may then be etched or otherwise removed to leave the final pattern on the top surface. The same process is repeated to form the solder mask layer on the bottom surface. The solder mask may be applied by other methods in further embodiments.

Referring again to the flowchart of FIG. 1, after formation of the solder mask layer 210 including the cavity 212 and dam 214, the electrical contacts 208 left exposed through the solder mask may be plated with a Ni/Au or the like in step 112 in a known electroplating or thin film deposition process. If plating is by electroplating, any electrical traces of the conductance pattern exposed in the bottom of the cavity 212 will also be plated. Alternatively, the conductance pattern may be formed so that the conductive layer 204 on the top surface of the substrate 202 is completely removed in the area of the cavity 212. If plating is by thin film deposition, the conductance pattern may be provided so that portions of the conductive layer 204 are visible, or are not visible, in the bottom of the cavity.

In step 116, the substrate 202 may then be inspected and tested in an automated inspection process, and in step 120, the substrate may undergo a final visual inspection, to check electrical operation, and for contamination, scratches and discoloration.

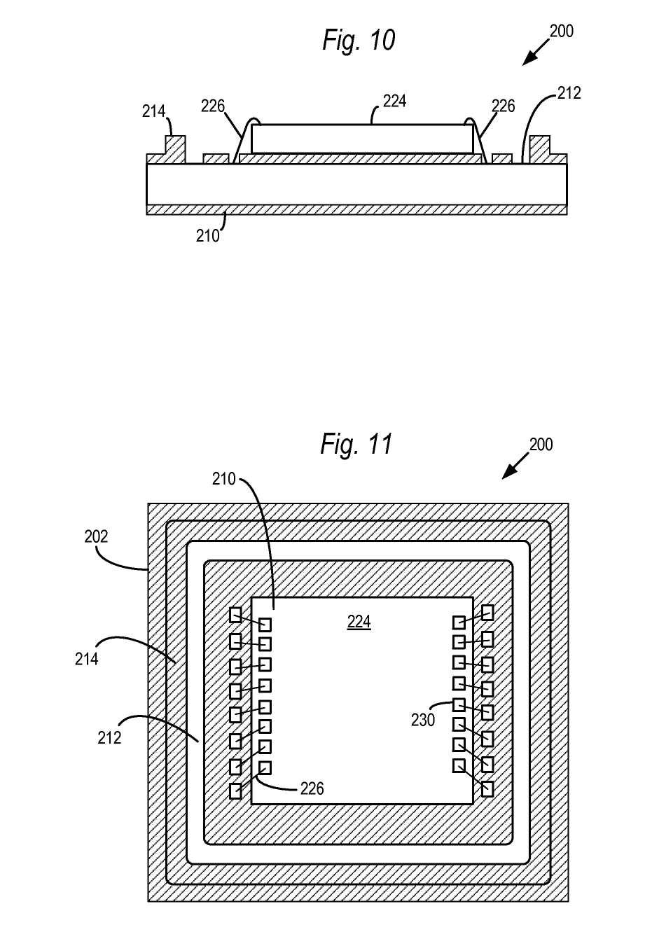

Assuming the substrate 202 passes inspection, one or more semiconductor die may next be affixed to the top surface of the substrate 202, on top of the solder mask layer 210, in a step 124. The one or more semiconductor die may then be wire bonded to the substrate 202 in a step 126. A semiconductor die 224 is shown wire bonded to the substrate 202 with wire bonds 226 in the edge and top views of FIGS. 10 and 11. The wire bonds 226 may be connected between die bond pads 230 on the die 224 and the contact pads 208 on the substrate 202. While the die bond pads 230 are shown on opposed sides of the die 224 in the figures, it is understood that the die bond pads 230 and wire bonds 226 may be on a single side of the die 224, two adjacent sides of the die 224, three sides or all four sides of the die 224.

In embodiments, the one or more semiconductor die 224 may comprise a single semiconductor die, as shown in FIGS. 10 and 11, which may for example be a controller die such as an ASIC. In embodiments including a single semiconductor die, the die may alternatively be a memory die such as for example a flash memory chip (NOR/NAND), though other types of memory die are contemplated. While a single semiconductor die 224 is shown, it is understood that a plurality of die may be included. Where multiple die 224 are used, the die may be one or more memory die and a controller die.

Although not shown, one or more passive components may also be affixed and electrically coupled to the substrate 202. The one or more passive components may be mounted on the substrate 202 and electrically coupled to the conductance pattern as by connection to contact pads in known surface mount and reflow processes. The passive components may include for example one or more capacitors, resistors and/or inductors, though other components are contemplated.

In step 128, the semiconductor device 200 may undergo a plasma clean process to remove particulate and to improve the wettability of the surface to allow better flow properties of a thermosetting material used to protect the semiconductor die and wire bonds.

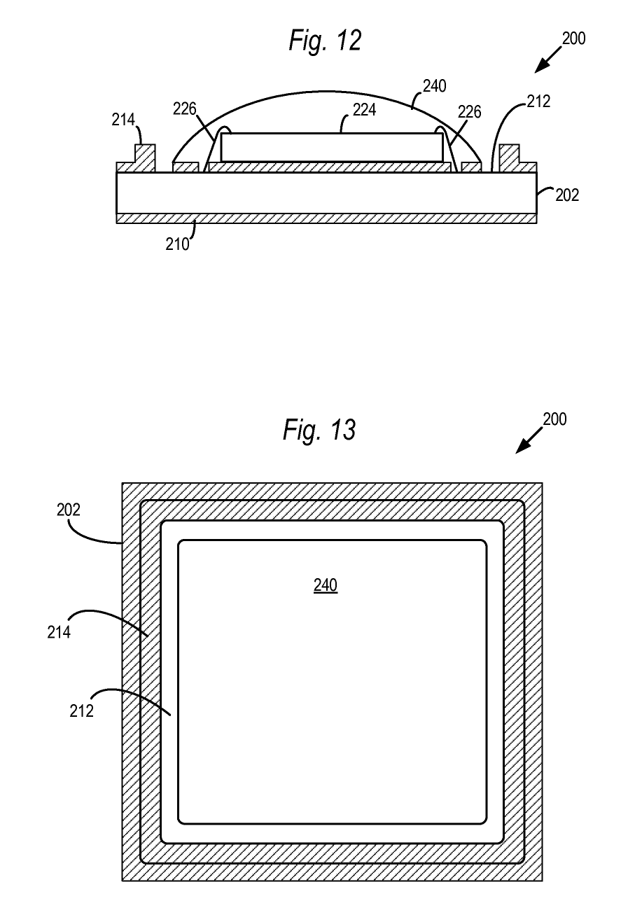

In particular, in step 130, after the die 224 have been mounted and wire bonded to the substrate, the die 224 and wire bonds 226 may be encapsulated in a cover in a glob top packaging process. Referring to the edge, top and perspective views of FIGS. 12-14, a glob top cover 240 may be applied over the semiconductor die 224 and wire bonds 226. The glob top cover 240 may be formed of any of various thermosetting materials such as epoxy, ceramic or glass.

As indicated above, the semiconductor devices 200 may be batch processed from a panel of substrates. A stencil mask may be used to simultaneously apply a discrete amount of thermosetting material onto each semiconductor device 200 in the panel of substrates. A variety of fluids can be used for glob top cover, including for example type DE109H, manufactured by Shenzhen Dover Technology Co., Ltd., Nanshan District, Shenzhen, China. The glob top cover may be provided by other manufacturers in further embodiments.

The glob top cover 240 may be applied as a viscous liquid at room temperature. Once applied, the semiconductor device 200 may undergo a vacuum step at elevated temperature to promote spreading of the glob top material across the surface of the solder mask 210 and to remove air bubbles from the glob top material. The vacuum step may be performed under vacuum conditions at a temperature of 80° C. for approximately fifteen minutes. It is understood that the pressure, temperature and duration of the vacuum step may each vary from that set forth above in alternative embodiments.

In the vacuum step, the glob top liquid spreads out over the semiconductor die 224, wire bonds 226 and solder mask layer 210, due to the forces of gravity and wettability of the surfaces over which the liquid glob top flows. In embodiments, parameters such as the wettability of the solder mask layer 210, the amount of glob top material applied, and the viscosity of the glob top material may be controlled relative to each other so that the glob top material spreads out until it reaches the cavity 212 around four sides of the device 200. In embodiments, the discontinuity in the surface of the solder mask 210 due to the sharp change in angle at the cavity 212 (e.g., 90°), together with the parameters such as the wettability of the solder mask layer 210, the amount of glob top material applied, and the viscosity of the glob top material, cause the glob top material to reach hydrostatic equilibrium and stop flowing once it reaches the edge of the cavity 212. In these embodiments, the glob top material does not flow into the cavity 212. In this manner, the cavity 212 controls the shape of the glob top cover 240.

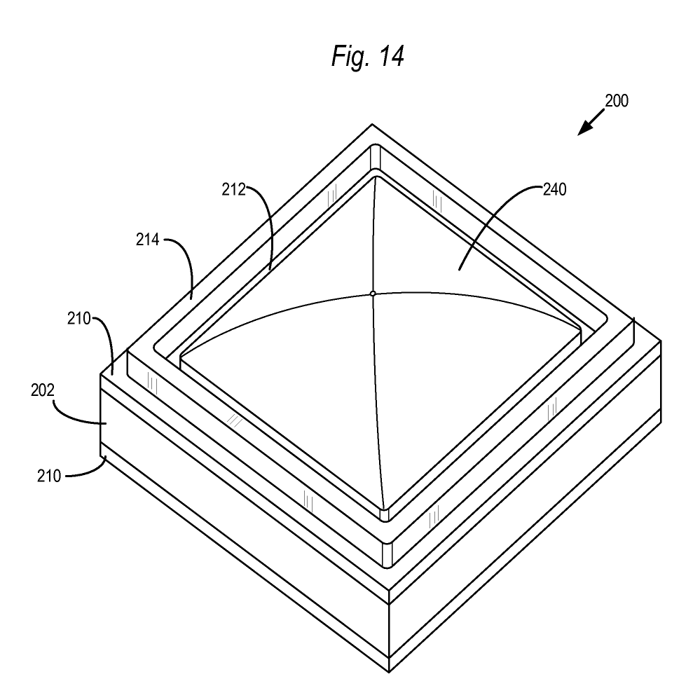

As shown in FIGS. 13 and 14, the glob top cover 240 may flow to the cavity 212 around the sides and to the corners of the semiconductor device 200. It is understood that one or more of the above-described parameters may be varied so that the glob top material does not flow all the way into each corner when in its liquid phase. In embodiments, the glob top cover 240 may completely encompass the semiconductor die 224 and wire bonds 226, and may extend about 0.47 mm above the substrate, though it may be higher or lower than that in further embodiments.

After the vacuum step, the applied glob top material may be heated and cured to harden the material into the cover 240, for example by heating the material in an oven at a temperature of 130° C. for thirty minutes. The temperature and length of time at which the material is heated may vary in alternative embodiments. The glob top cover 240 may be opaque or transparent.

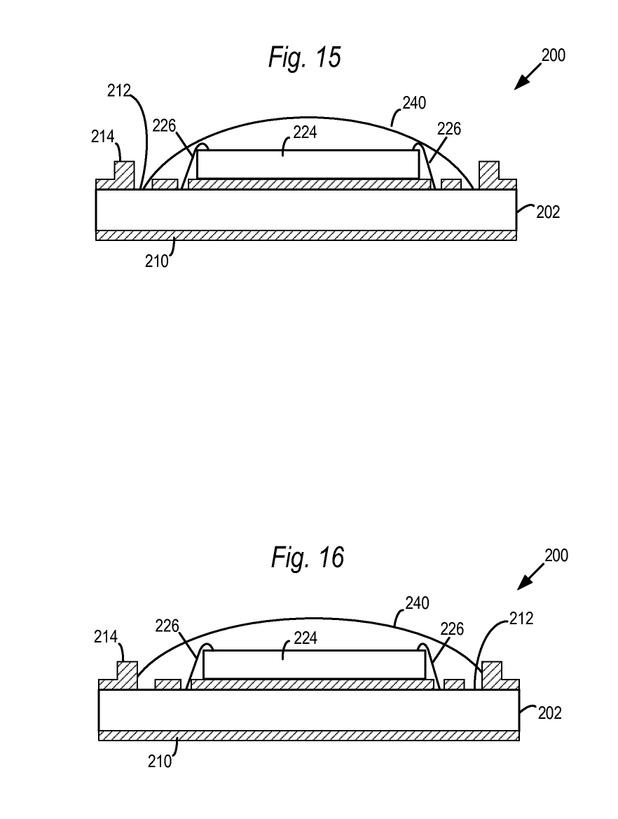

As noted above, in embodiments, the glob top material flows to the cavity 212, but does not enter the cavity 212. However, in a further embodiment shown in FIG. 15, the cavity may provide overflow for the glob top material. In this embodiment, the glob top material flows into the cavity 212. In a further embodiment, the glob top material may flow into the cavity 212, and then rise up the outer side wall of the cavity 212 (sidewall sw in FIG. 7). The dam 214 provides a further line of defense to prevent bleeding of the glob top material beyond intended boundaries.

In the embodiments described above, the semiconductor device 200 includes both a cavity 212 and a dam 214. However, it is contemplated in further embodiments that one or the other of the cavity 212 or the dam 214 may be omitted. In such embodiments the single formation (either the cavity 212 or dam 214) prevents bleeding of the glob top material beyond intended boundaries.

Furthermore, in embodiments described above, the cavity 212 and dam 214 extend around the entire periphery of the semiconductor device 200. However, in embodiments where for example the glob top material reaches hydrostatic equilibrium without flowing into the corners of the device 200, the cavity 212 and/or the dam 214 may be omitted from the corners of the device (i.e., omitted from areas adjacent to corners of the semiconductor die 224). The partial cavity 212 and/or dam 214 may be provided, and then the parameters of the solder mask and glob top material set so that the glob top material does not flow around the partial cavity 212 and/or dam 214. Alternatively, the flow pattern of the glob top material may be determined, and then the partial cavity 212 and/or dam 214 provided so as to ensure the cavity 212 and/or dam 214 are long enough on each side so that the glob top material does not flow around the partial cavity 212 and/or dam 214.

After formation of the glob top cover 240, the semiconductor devices 200 may be singulated from the panel in step 134 to form the finished semiconductor device 200 shown in FIGS. 12-14. Each device 200 may be singulated by any of a variety of cutting methods including sawing, water jet cutting, laser cutting, water guided laser cutting, dry media cutting, and diamond coating wire cutting. While straight line cuts will define a generally rectangular or square shaped device 200, it is understood that device 200 may have shapes other than rectangular and square in further embodiments of the present invention.

Once cut into devices 200, the devices may be tested in a step 136 to determine whether the packages are functioning properly. As is known in the art, such testing may include electrical testing, burn in and other tests. The devices may optionally be encased within a lid in step 140.

In summary, in one embodiment, the present technology relates to a semiconductor package, comprising: a substrate; a solder mask layer including at least one of a dam protruding above surrounding areas of the solder mask layer and a cavity recessed into the solder mask layer; a semiconductor die affixed to the solder mask layer and electrically coupled to the substrate through the solder mask layer; and a glob top cover applied as a liquid and hardened to a solid, the at least one of the dam and cavity in the solder mask layer limiting flow of the glob top cover upon application of the liquid glob top cover.

In a further embodiment, the present technology relates to a semiconductor package, comprising: a substrate; a solder mask layer including a cavity recessed into the solder mask layer; a semiconductor die affixed to the solder mask layer and electrically coupled to the substrate through the solder mask layer; and a glob top cover applied as a liquid and hardened to a solid, the glob attaining hydrostatic equilibrium lying in contact with at least portions of an edge of the cavity after being applied as a liquid to the semiconductor package.

In a further embodiment, the present technology relates to a semiconductor package, comprising: a substrate; a solder mask layer including a dam protruding above surrounding areas of the solder mask layer and a cavity recessed into the solder mask layer, the dam positioned adjacent to and radially outward of the cavity; a semiconductor die affixed to the solder mask layer and electrically coupled to the substrate through the solder mask layer; and a glob top cover applied as a liquid and hardened to a solid, a dam and a combination of parameters limiting flow of the glob top cover to at least portions of an edge of the cavity upon application of the liquid glob top cover, the combination of parameters including a wettability of the solder mask layer, an amount of glob top material applied, and a viscosity of the glob top material when applied.

The foregoing detailed description of the invention has been presented for purposes of illustration and description. It is not intended to be exhaustive or to limit the invention to the precise form disclosed. Many modifications and variations are possible in light of the above teaching. The described embodiments were chosen in order to best explain the principles of the invention and its practical application to thereby enable others skilled in the art to best utilize the invention in various embodiments and with various modifications as are suited to the particular use contemplated. It is intended that the scope of the invention be defined by the claims appended hereto.

We claim:

1. A semiconductor package, comprising:
a substrate;
a solder mask layer including at least one of a dam protruding above surrounding areas of the solder mask layer and a cavity recessed into the solder mask layer;
a semiconductor die affixed to the solder mask layer and electrically coupled to the substrate through the solder mask layer; and
a glob top cover applied as a liquid and hardened to a solid, the at least one of the dam and cavity in the solder mask layer limiting flow of the glob top cover upon application of the liquid glob top cover.

2. The semiconductor package as recited in claim 1, wherein the solder mask includes a cavity and a discontinuity in the surface of the solder mask due to the cavity prevents the liquid of the glob top cover from flowing into the cavity.

3. The semiconductor package as recited in claim 1, wherein the solder mask includes dam and the cavity.

4. The semiconductor package as recited in claim 3, wherein the cavity is adjacent to and radially inward of the dam.

5. The semiconductor package as recited in claim 3, wherein the cavity is a band extending around all sides and corners of the semiconductor package.

6. The semiconductor package as recited in claim 3, wherein the dam is a band extending around all sides and corners of the semiconductor package.

7. The semiconductor package as recited in claim 3, wherein the dam and cavity are rectangular shaped rings.

8. The semiconductor package as recited in claim 3, wherein the dam and cavity are rectangular shaped rings with rounded edges in corners.

9. The semiconductor package as recited in claim 3, wherein the dam and cavity are round shaped rings.

10. A semiconductor package, comprising:
a substrate;
a solder mask layer including a cavity recessed into the solder mask layer;
a semiconductor die affixed to the solder mask layer and electrically coupled to the substrate through the solder mask layer; and
a glob top cover applied as a liquid and hardened to a solid, the glob attaining hydrostatic equilibrium lying in contact with at least portions of an edge of the cavity after being applied as a liquid to the semiconductor package.

11. The semiconductor package as recited in claim 10, wherein a discontinuity in the surface of the solder mask due to the cavity prevents the liquid of the glob top cover from flowing into the cavity.

12. The semiconductor package as recited in claim 10, wherein the solder mask further includes dam extending above the surrounding surface of the solder mask, the dam providing a further line of defense against the glob top cover flowing radially outward of the dam.

13. The semiconductor package as recited in claim 12, wherein the dam is adjacent to and radially outward of the cavity.

14. The semiconductor package as recited in claim 10, wherein the cavity is a band extending around all sides and corners of the semiconductor package.

15. The semiconductor package as recited in claim 10, wherein the cavity includes sections extending around sides but not corners of the semiconductor package.

16. A semiconductor package, comprising:
a substrate;
a solder mask layer including a dam protruding above surrounding areas of the solder mask layer and a cavity recessed into the solder mask layer, the dam positioned adjacent to and radially outward of the cavity;
a semiconductor die affixed to the solder mask layer and electrically coupled to the substrate through the solder mask layer; and
a glob top cover applied as a liquid and hardened to a solid, a dam and a combination of parameters limiting flow of the glob top cover to at least portions of an edge of the cavity upon application of the liquid glob top cover, the combination of parameters including a wettability of the solder mask layer, an amount of glob top material applied, and a viscosity of the glob top material when applied.

17. The semiconductor package as recited in claim 16, wherein the cavity and dam are rectangular bands.

18. The semiconductor package as recited in claim 16, wherein the cavity and dam are rounded bands.

19. The semiconductor package as recited in claim 16, wherein the cavity and dam extend around an entire periphery of the semiconductor die.

20. The semiconductor package as recited in claim 16, wherein the cavity and dam are omitted from sections adjacent corners of the semiconductor die.
